(19) United States
(12) Patent Application Publication
(10) Pub. No.: US 2025/0212362 A1
(43) Pub. Date: Jun. 26, 2025

(54) COOLING ARRANGEMENT WITH A HEAT SINK FOR AT LEAST ONE MICROCHIP

(71) Applicant: RITTAL GMBH & CO. KG, Herborn (DE)

(72) Inventors: Juan Carlos CACHO ALONSO, Braunschweig (DE); Andreas MEYER, Fronhausen (DE); Jörg KNETSCH, Ehringshausen (DE)

(21) Appl. No.: 18/847,496

(22) PCT Filed: Feb. 10, 2023
(86) PCT No.: PCT/DE2023/100110

§ 371 Date: Sep. 16, 2024

(30) Foreign Application Priority Data
Apr. 13, 2022 (DE) 10 2022 109 148.1

(51) Int. Cl. H05K 7/20; G06F 1/20

(52) U.S. Cl. CPC H05K 7/20254; G06F 1/20; H05K 7/20272; H05K 7/20309; H05K 7/20327; G06F 2200/201

(57) ABSTRACT

A heat sink for at least one microchip having a heat-conducting heat sink which has a channel structure for a cooling fluid with a feed and a return, wherein the heat sink has, on two opposite outer sides, in each case one cooling plate which is coupled thermally and mechanically to the channel structure. Furthermore, a corresponding cooling arrangement is described.

### CROSS-REFERENCE TO RELATED APPLICATIONS

This application is a U.S. National Phase application under 35 U.S.C. 371 of International Application No. PCT/DE2023/100110, filed on Feb. 10, 2023, which claims the benefit of German Patent Application No. 10 2022 109 148.1, filed on Apr. 13, 2022. The entire disclosures of the above applications are incorporated herein by reference.

### BACKGROUND

This section provides background information related to the present disclosure which is not necessarily prior art.

### TECHNICAL FIELD

The invention is based on a cooling arrangement having a heat sink, frequently also referred to as a “cold plate”, for at least one electronic component, having a heat-conducting heat sink which has a channel structure for a cooling fluid with a feed and a return. Such a heat sink is described in U.S. Pat. No. 10,485,143 B2. A heat sink having the features of the preamble of Claim 1 is disclosed in US 2009/0114373 A1. Similar arrangements are also described in JP 4027353 B2 and EP 2 386 194 B1. Further cooling elements are likewise disclosed in US 2010/0084120 A1 and DE 21 2012 000 223 U1. A heat sink manufactured using an additive method is described in US 2021/0247140 A1. A cooling arrangement with the features of the generic term of claim 1 is described in U.S. Pat. No. 5,131,859 A.

### DISCUSSION

With the computing power of many electronic components, for instance IT components such as microchips (CPUs, GPUs, etc.), AC converters and the like, their power loss and therefore the heat development also increases. The progressive further development, for instance in the field of microchip technology, enables powers of in some cases more than 400 watts per chip. Owing to the increased power density, the known air-cooled heat sinks and heat sinks are no longer suitable for dissipating the resulting power loss to a sufficient extent, taking into account the limited space conditions, for example in server housings. Although new cooling technologies, such as “direct chip cooling”, enable the microchips to be cooled effectively. On the other hand, however, these technologies are substantially more complex and comparatively less robust to failures than the known heat sinks. The heat pipes known from the prior art, based on copper tubes and aluminum laminations, also have only a limited cooling capacity. In principle, there is an endeavor to maximize the performance of the electronic components and at the same time to offer a product with the lowest possible costs. One possibility for reducing the infrastructure and its costs is to make better use of the available space on the server and to increase the computing power of the server without thereby increasing the available volume. This also enables existing data centers to be upgraded with a higher computing power in the case of a given space requirement.

### SUMMARY

This section provides a general summary of the disclosure and is not a comprehensive disclosure of its full scope or all of its features.

It is therefore one aspect of the invention to further develop a cooling arrangement of the type described at the outset in such a way that it provides a high cooling power with a low space requirement.

The invention is based on the idea of configuring the heat sink in a plate-shaped, therefore planar, manner in order, with a small dimension perpendicular to the opposite outer sides, to provide as large an area as possible for the conductive heat transfer from a microchip in need of cooling to the heat sink.

As a result, not only one of the two opposite outer sides of the heat sink is to be used for cooling an electronic component in need of cooling, but rather both sides are to be used for cooling preferably at least one electronic component. With respect to the two outer sides having the cooling plates, the heat sink, in particular the heat-conducting heat sink thereof, can be configured symmetrically, such that the heat sink has, in two positions rotated through 180° with respect to one another, an identical cooling plate for the thermal coupling of an electronic component in need of cooling.

If the channel structure of the heat sink is coupled thermally to both of the cooling plates arranged on the opposite outer sides, the cooling power provided by the heat sink is provided equally by both cooling plates. The heat sink can therefore also be configured symmetrically with respect to the two cooling plates with regard to the channel structure. For example, the heat sink can be fully symmetrical with respect to a central plane of the heat sink, which central plane extends parallel to the two cooling plates. The forward flow and the return flow can be arranged on an end side of the heat sink, which end side is oriented perpendicular to the cooling plates, such that they do not constitute a disruptive structure with respect to the mounting of electronic components in need of cooling on the opposite cooling plates.

If a cooling fluid is described in the present application, it can be a single-phase cooling fluid, but also a multiphase cooling fluid, in particular a two-phase cooling fluid with a liquid phase and a vapor phase, for example a cooling fluid which has a vapor phase.

In order to provide a particularly good thermal conductivity of the heat sink and therefore as uniform as possible a distribution of the cooling power over the volume of the heat sink or over the area of the at least one cooling plate, the heat sink, in particular at least the at least one cooling plate and the channel structure, can be configured in one piece in an additive manufacturing method, for example by means of build-up welding.

The channel structure can be guided through the heat sink in a meandering manner and parallel to the at least one or both cooling plates. In order to achieve as high a channel structure length as possible, the channel structure can have at least two channel sections which pass through the heat sink substantially parallel to one another and preferably packed as tightly as possible, wherein, on opposite end sides of the heat sink, at least one fluidic transition can be provided between the at least two channel sections, within which fluidic transition successive ones of the at least two parallel channel sections are connected to one another via a 180° deflection, in order to form the meandering channel structure.

The channel structure preferably consists of a plurality of channel sections which are connected to one another via fluidic transitions, wherein at least one of the channel sections consists, at least in sections, of a plurality of sub-channels which are fluidically separated from one another along the channel section. The sub-channels can extend in particular parallel to one another. The sub-channels can be fluidically separated from one another via partition walls. The partition walls can be coupled thermally, on opposite longitudinal sides, in each case to the at least one or to both of two opposite cooling plates, preferably be formed in one piece with the cooling plate or the cooling plates, in order to achieve an optimum heat transfer between the at least one cooling plate and the fluid flowing through the sub-channels. Consequently, the partition walls preferably themselves consist of a heat-conducting material. If a thermal transition is provided between the partition walls and at least one cooling plate, the partition walls can contribute to the heat exchange to the fluid flowing through the sub-channels.

The sub-channels which are separated from one another can be coupled thermally in each case to both cooling plates. Consequently, the sub-channels can extend directly as far as the opposite cooling plates, such that a fluid flowing through the sub-channels is in thermal contact with the cooling plates.

The sub-channels can extend at least in part, preferably at least all, over a complete distance between the two cooling plates.

The channel section with the plurality of sub-channels which are fluidically separated from one another along the channel section can open directly into the fluidic transition with all sub-channels. It is therefore in particular not necessary for the sub-channels to be combined with one another before they open into the fluidic transition. The fluid streams which are separated from one another by the sub-channels can be combined only in the fluidic transition. All of the sub-channels of the channel section which feeds the transition and also all of the sub-channels of the channel section which is fed from the fluidic transition can therefore open into the fluidic transition in the flow direction. The transition can be configured as a recess close to an end side of the heat sink, into which recess all of the abovementioned sub-channels of the feeding and of the fed channel section open.

The channel structure can have a plurality of channel sections which consist, at least in sections, of a plurality of sub-channels which are fluidically separated from one another along the respective channel section. The channel sections preferably have a different number of sub-channels. It is particularly preferably provided that, in the flow direction from the feed to the return, a second channel section which follows a first of the channel sections has a greater number of sub-channels than the first channel section. The increase in the number of channels in each channel section is set up to compensate for the increase in volume of the cooling medium owing to the evaporation of the liquid. The more liquid passes into the gaseous state, the more volume it takes up in order to keep the pressure loss in the channels substantially constant. When using a liquid medium such as water, it is possible to dispense with increasing the number of channels in each channel section.

In particular, the sum of the channel cross sections of the sub-channels of the first channel section can be smaller than the sum of the channel cross sections of the sub-channels of the second channel section. In this case, it is possible to aim at keeping the cooling fluid speed and therefore the pressure loss constant. In the case of a cooling fluid consisting substantially of a liquid phase, the flow speed in the second channel section decreases in relation to the first channel section, so that, owing to the longer residence time of the cooling fluid in the second channel section in conjunction with the channel wall surface area which is increased owing to the increased number of sub-channels, a sufficient or constant cooling power is still provided even when the cooling fluid temperature has increased in relation to the first channel section. The increasing number of sub-channels and the flow cross section of the channel section which is increased therefore in relation to a channel section which precedes in the flow direction can also serve to compensate for an increase in volume of the refrigerant used, in particular when it is a 2-phase refrigerant which, when passing through the heat sink and with increasing heat transfer to the refrigerant, passes with increasing proportion from the liquid phase into the gaseous phase and accordingly takes up a larger volume.

The channel sections can, in the flow direction from the feed to the return, have a constantly increasing number of sub-channels from channel section to channel section.

The sub-channels of all channel sections can run parallel to one another, wherein the sub-channels preferably have a constant and particularly preferably a substantially identical or identical channel cross section for all sub-channels.

The channel section which opens into the return, and consequently ends in the flow direction, can have a channel width which corresponds to at least twice, preferably at least three times and particularly preferably at least four times the width of the channel section which opens into the feed.

The return can have a cross section which is at least twice as large, preferably at least three times as large and particularly preferably at least four times as large as the feed. As a result, an optimum discharge of the heated fluid from the heat sink is ensured even at low fluid pressures or low flow speeds.

According to another aspect, a cooling arrangement having at least one heat sink of the type described above and at least two electronic components is described. The heat sink has, on its two opposite outer sides, in each case one cooling plate. In this case, it is provided that the electronic components, with their heat-emitting side facing one another, are in thermal contact with the opposite outer sides of the cooling plate.

The electronic components and the opposite outer sides of the cooling plates can have complementary fastening means, preferably through-holes and threaded receptacles.

It can be provided that the heat sink, with the electronic components mounted thereon on the opposite cooling plates, constitutes a preassembled assembly, for instance a preassembled assembly of a relatively large IT unit, for example of a server housing, in which it is mounted, for example by the two electronic components being inserted via plug connectors into slots of a main circuit board. In this case, the heat sink forms a load-bearing structure for the electronic components. The heat sink is thus particularly suitable for retrofitting existing IT infrastructures, since, by inserting the electronic components already preassembled on the heat sink, the electronic components are retrofitted and the liquid cooling is provided in a single assembly step.

The electronic components can be designed as plug-in cards, wherein the plug-in cards can have, along an outer edge, a plug connector for the vertical assembly and electrical connection of the electronic components to in each case one separate slot of a multiplicity of slots on a main circuit board. In this case, the distance between the outer sides of the heat sink can be dimensioned precisely such that the two electronic components have, between their plug connectors, a distance with respect to one another which corresponds to a grid spacing of the multiplicity of slots.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations and are not intended to limit the scope of the present disclosure.

Further details of the invention will be explained with reference to the accompanying figures. In the figures:

FIG. 1 shows, in a perspective illustration, an exemplary embodiment of a heat sink according to the invention;

FIG. 2 shows a sectional view of the heat sink according to FIG. 1;

FIG. 3 shows a detailed view of the heat sink according to FIG. 2;

FIG. 4 shows the heat sink according to FIG. 2 in a perspective illustration;

FIG. 5 shows a detailed view of the heat sink according to FIG. 4;

FIG. 6 shows, in a perspective illustration, a further exemplary embodiment of a heat sink according to the invention;

FIG. 7 shows a sectional view of the heat sink according to FIG. 6;

FIG. 8 shows, in a schematic illustration, a cooling arrangement according to the invention;

FIG. 9 shows a detailed view of the cooling arrangement according to FIG. 8; and

FIG. 10 shows a side view of the cooling arrangement according to FIG. 8;

### DETAILED DESCRIPTION

Example embodiments will now be described more fully with reference to the accompanying drawings.

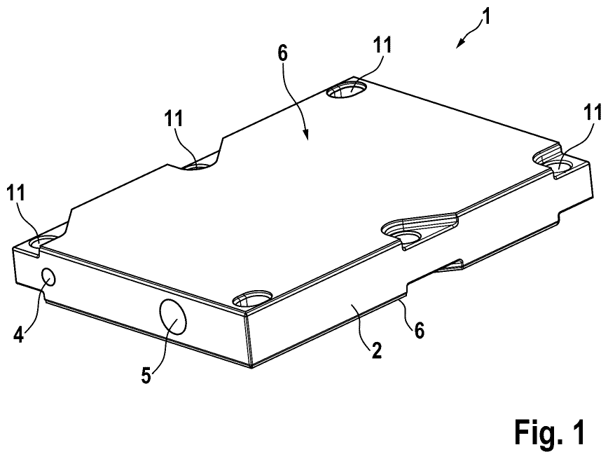

FIG. 1 shows an exemplary embodiment of a heat sink 1 according to the invention. The heat sink 1 substantially consists of a heat-conducting heat sink 2 which has, in the interior, a channel structure for a cooling fluid which are fluidically accessible via a forward flow 4 and a return flow 5 on an end side of the heat sink 2. In a departure from the heat sinks known from the prior art, the heat sink 2 has, on both of its opposite outer sides, in each case one cooling plate 6 which is coupled thermally via the channel structure in the interior of the heat sink 2 and is therefore supplied in each case with cooling power. Both cooling plates 6 can therefore be brought into thermal contact for the mounting of an IT component in need of cooling, for example with a CPU or a GPU, for example by virtue of the said electronic component being mounted with a heat-emitting side directly on the cooling plate 6.

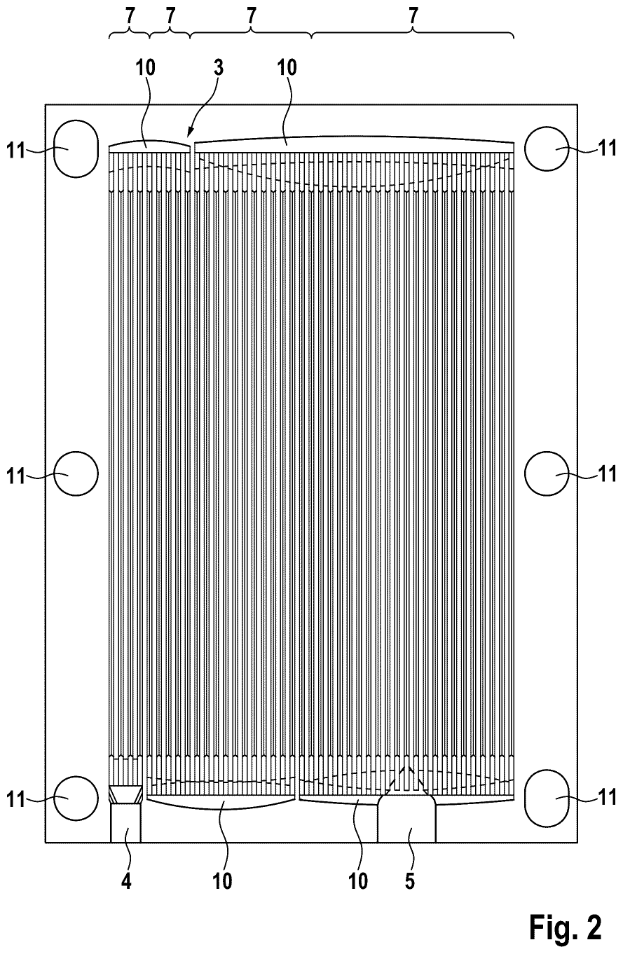

FIGS. 2 to 5 show in particular the channel structure 3 which is formed in the interior of the heat sink 2 and is coupled thermally and mechanically to the two opposite cooling plates 6 of the heat sink 2.

The channel structure 3 consists of channel sections 7 which extend parallel to one another and which extend through the heat sink 2 in a meandering manner and parallel to the cooling plates 6. The channel sections 7 are divided in each case into a multiplicity of sub-channels 8. The sub-channels 8 of the same channel section 7 are fluidically isolated from one another via partition walls 9 which separate the sub-channels, such that no liquid exchange takes place between the sub-channels along the profile of the sub-channels 8. All of the sub-channels 8 of the same channel section 7 open into a fluidic transition 10 at an end side of the heat sink 2, where the sub-volume streams of the sub-channels 8 are then combined. Furthermore, the combined sub-volume streams are deflected by 180° in the fluid flow direction in the transition 10 and are transferred into a following channel section 7, wherein the volume stream is in turn divided into a multiplicity of sub-channels 8.

As can be seen, the channel structure 3 has four channel sections 7 which are each divided into a different number of sub-channels 8. In the fluid flow direction from the feed 4 to the return 5, each following channel section 7 has a higher number of sub-channels 8 with respect to the channel section 7 which precedes in the flow direction, wherein all of the sub-channels 8 of the heat sink 2 have the same opening cross section. The increase in the number of sub-channels therefore results in a reduction in the flow speed at the transition into each channel section 7 which follows in the flow direction. Furthermore, the number of partition walls 9 and the area of the cooling plates 6 with which the channel section or the fluid passing through the channel section is in thermal contact is increased, as a result of which a substantially constant cooling power with respect to the cooling plates 6 can be provided even when the cooling fluid temperature increases.

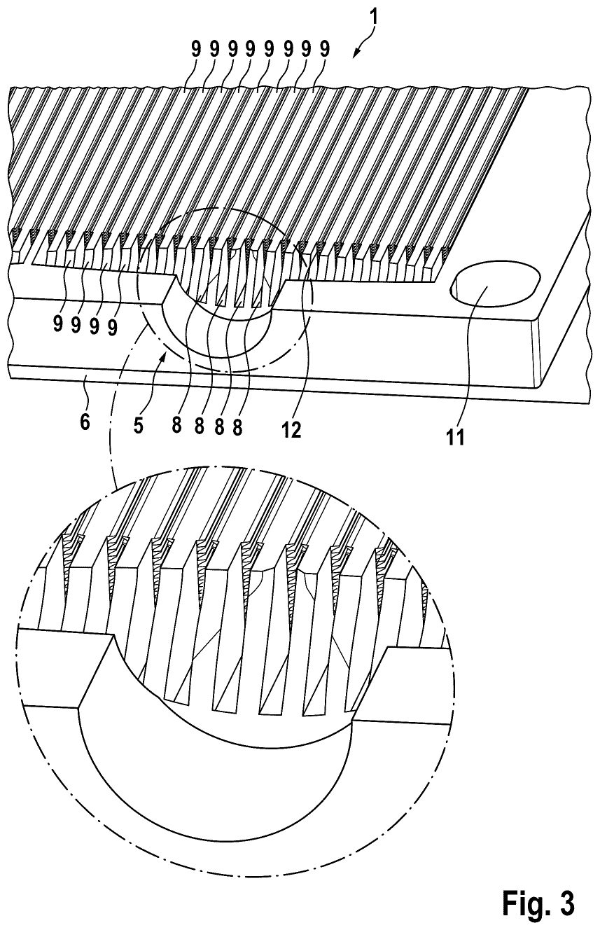

FIG. 3 furthermore illustrates that the partition walls 9 are configured in one piece with the cooling plate 6, for example with the aid of an additive manufacturing method. Furthermore, the partition walls 9 have, on their inner sides facing the sub-channel 8, a surface structure 12, as a result of which the effective cross section between the cooling fluid and the partition wall is increased and, if appropriate, turbulences can be generated. Turbulence can be generated in order to improve the heat exchange between the cooling fluid and the partition walls 9. Since the partition walls 9 pass directly into the cooling plates 6 or can even be configured in one piece with the cooling plates 6, an optimum heat transfer from the cooling plate 6 via the partition walls 9 and the surface structure 12 to the cooling fluid flowing through the sub-channels 8 is achieved.

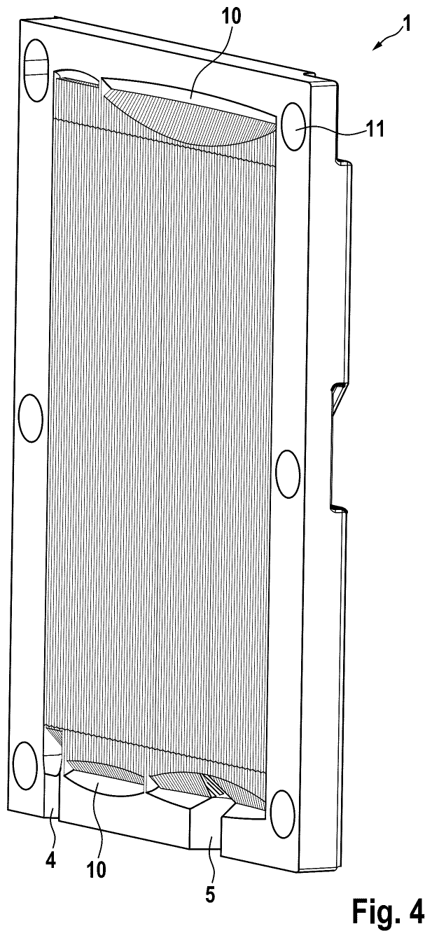

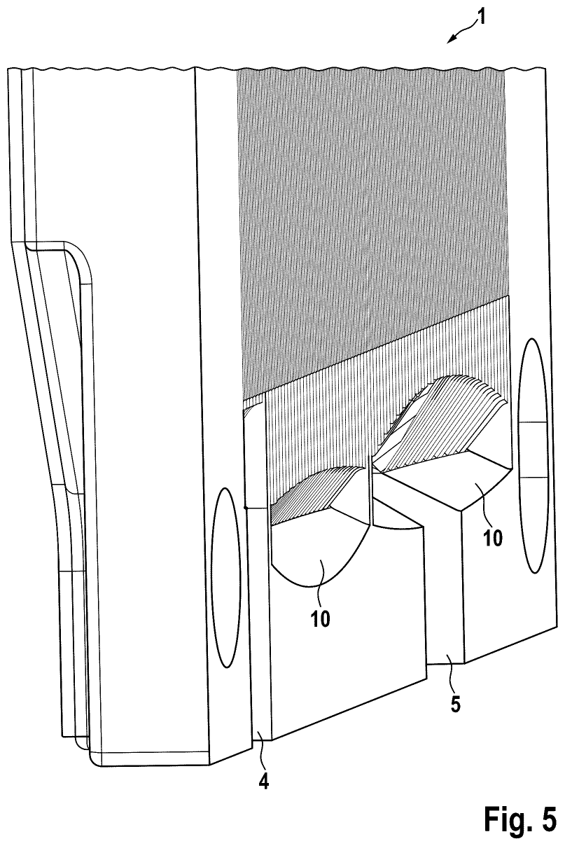

FIGS. 4 and 5 illustrate that the fluidic transitions 10 can be configured as recesses which are designed particularly advantageously for the construction with the aid of an additive manufacturing method, wherein all of the sub-channels 8 of the two channel sections 7 which are fluidically connected to one another via the transition 10 open into the transition 10.

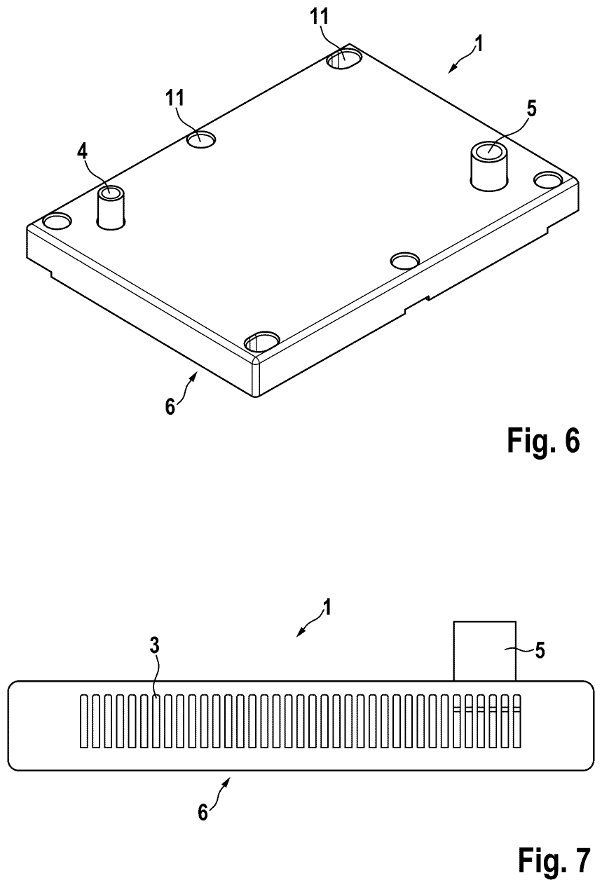

FIGS. 6 and 7 show a further embodiment of a heat sink 1 according to the invention which, in contrast to the embodiments described above, has, on only one of its two opposite sides, a cooling plate 6 and, on the side opposite the cooling plate 6, a feed 4 and a return 5. The cross section according to FIG. 7 furthermore illustrates the preferred single-piece embodiment of the heat sink 1, as a result of which, on the one hand, the optimum heat transfer between the heat sink 1 and the cooling fluid flowing through the heat sink 1 and, on the other hand, an optimum heat distribution within the heat sink 1 is achieved and therefore the entire heat capacity of the heat sink 1 is available for the heat transfer from an electrical component in need of cooling to the heat sink 1. The heat sink 1 according to FIGS. 6 and 7 is preferably produced in an additive method, as a result of which the mentioned single-piece nature is ensured.

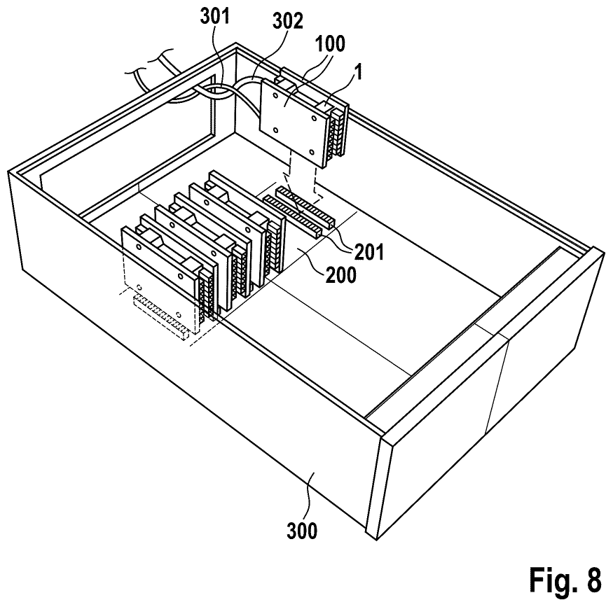

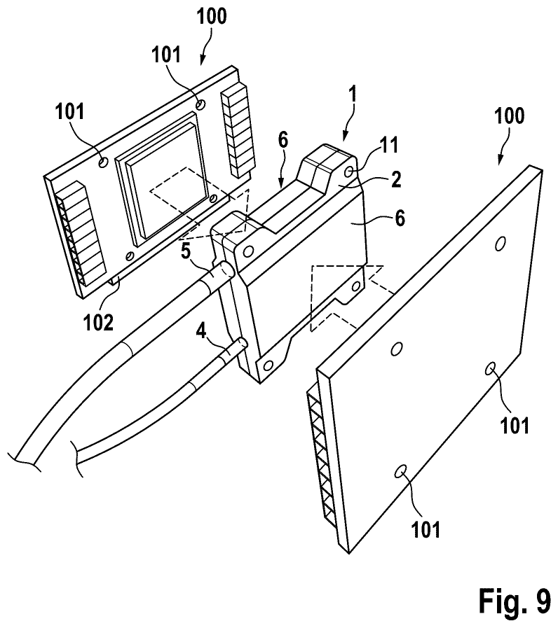

FIGS. 8 to 10 describe an embodiment of a cooling arrangement according to the invention in which, on opposite outer sides which form the cooling plates 6 (cf. FIG. 1), in each case one electronic component 100, here a GPU, is mounted, for example screwed, such that the electronic component 100 is in heat-transferring contact with in each case one of the two opposite cooling plates 6. The IT components 100 are configured as plug-in cards which, for the installation in a server housing 300, can be mounted in corresponding slots 201 on a main circuit board 200, as is known from the prior art. In contrast to the prior art, the heat sink 1 according to the invention enables two IT components 100, with the heat sink 1 positioned between them, to form a preassemblable assembly which can be mounted in a single assembly step, namely by inserting the plug-in connectors 102 of the two IT components 100 into in each case one of the slots 201 in the housing 300 or on the main circuit board 200, without further assembly steps being necessary in order to provide the cooling of the IT components. If appropriate, it is merely still necessary to connect the feed line 301 and the return line 302 to the feed or the return of the heat sink 1.

Particularly advantageously, therefore, the heat sink 1 has a dimension perpendicular to the two cooling plates 6 which, when IT components 100 are mounted on the cooling plates 6, defines a distance with respect to the two plug connectors 102 of the IT components 100 which corresponds to the distance between the two slots 201 or a grid spacing of the multiplicity of slots 201.

The heat sink 1 and the IT components 100 can have complementary fastening means via which the IT components can be connected to the heat sink 1 in a force-fitting manner in order to form a one-piece structural unit. For example, the IT components 100 can have through-holes 101 and the heat sink 1 can have threaded bores 11 with the aid of which the IT components 100 can be screwed to the heat sink 1.

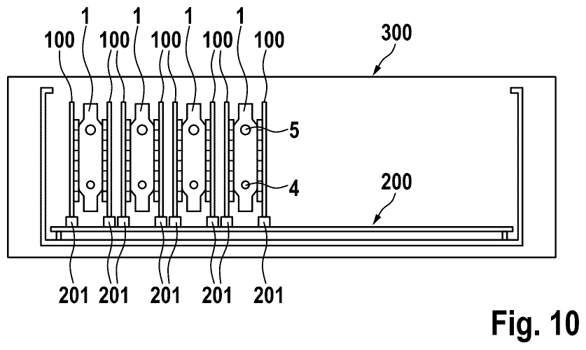

FIG. 10 illustrates that, with the aid of the heat sink 1 according to the invention, a maximum packing density of the IT components 100 in the server housing 300 can be achieved. In particular, the heat sink 1 can have a dimension perpendicular to the cooling plates 6 which is dimensioned precisely such that, in the case of a given grid dimension of the slots 201 according to the industry standard and in the case of IT components 100 mounted with their heat-emitting sides facing one another in these slots 201, the heat sink 1 fills precisely the remaining intermediate space between the heat-emitting sides of the IT components 100 facing one another, such that, in addition to an optimum space utilization, an optimum heat transfer between the components 100 and the heat sink 1 is also ensured.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-15. (canceled)

16. A cooling arrangement comprising a heat sink for at least one microchip, preferably a GPU or CPU, having a heat-conducting heat sink which has a channel structure for a cooling fluid with a feed and a return, wherein the heat sink has, on two opposite outer sides, in each case one cooling plate which is coupled thermally and mechanically to the channel structure, and having at least two microchips which, with their heat-emitting side facing one another, are in thermal contact with the opposite outer sides of the cooling plate,
wherein
the microchips are designed as plug-in cards, wherein the plug-in cards have, along an outer edge, a plug connector for the vertical assembly and electrical connection of the electronic components to in each case one separate slot of a multiplicity of slots on a main circuit board, wherein the distance between the outer sides of the heat sink is dimensioned such that the two electronic components have, between their plug connectors, a distance which corresponds to a grid spacing of the multiplicity of slots.

17. The cooling arrangement according to claim 16, in which the channel structure is guided through the heat sink in a meandering manner and parallel to the at least one cooling plate or to both cooling plates.

18. The cooling arrangement according to claim 16, in which the channel structure consists of a plurality of channel sections which are connected to one another via fluidic transitions, wherein at least one of the channel sections consists, at least in sections, of a plurality of sub-channels which are fluidically separated from one another along the channel section.

19. The cooling arrangement according to claim 18, in which the sub-channels which are separated from one another are coupled thermally to the at least one cooling plate or to both cooling plates, wherein the sub-channels are preferably fluidically separated from one another via partition walls which are coupled thermally and mechanically to the at least one cooling plate or to both cooling plates and are particularly preferably formed in one piece with the at least one cooling plate or with both cooling plates.

20. The cooling arrangement according to claim 18, in which the sub-channels extend at least in part and preferably all over a complete distance between the two cooling plates when the heat sink has, on the opposite outer sides, in each case one cooling plate.

21. The cooling arrangement according to claim 18, in which the channel section with the plurality of sub-channels which are fluidically separated from one another along the channel section opens directly into the fluidic transition with all sub-channels.

22. The cooling arrangement according to claim 18, in which the channel structure has a plurality of channel sections which consist, at least in sections, of a plurality of sub-channels which are fluidically separated from one another along the respective channel section, wherein the channel sections have a different number of sub-channels.

23. The cooling arrangement according to claim 22, in which, in the flow direction from the feed to the return, a second channel section which follows a first of the channel sections has a greater number of sub-channels than the first channel section.

24. The cooling arrangement according to claim 22, in which the channel sections, in the flow direction from the feed to the return, have a constantly increasing number of sub-channels from channel section to channel section.

25. The cooling arrangement according to claim 17, in which the sub-channels of all channel sections run parallel to one another, wherein the sub-channels preferably have a constant and particularly preferably a substantially identical or identical channel cross section for all sub-channels.

26. The cooling arrangement according to claim 17, in which a channel section which opens into the return has a channel width which corresponds to at least twice, preferably at least three times and particularly preferably at least four times the width of the channel section which opens into the feed.

27. The cooling arrangement according to claim 17, in which the return has a cross section which is at least twice as large, preferably at least three times as large and particularly preferably at least four times as large as the feed.

28. The cooling arrangement according to claim 16, in which the microchips and the opposite outer sides of the cooling plates have complementary fastening means, preferably through-holes and threaded receptacles.
